(19) United States
(12) Patent Application Publication
(10) Pub. No.: US 2017/0013732 A1
(43) Pub. Date: Jan. 12, 2017

(54) LOCKING APPARATUS FOR A SWITCHGEAR CABINET

(71) Applicant: ABB Schweiz AG, Baden (CH)

(72) Inventor: Manfred Kipfer, Eschenbach (CH)

(21) Appl. No.: 15/271,638

(22) Filed: Sep. 21, 2016

Related U.S. Application Data
(63) Continuation of application No. PCT/EP2015/051734, filed on Jan. 28, 2015.

(30) Foreign Application Priority Data
Mar. 21, 2014 (EP) 14161088.1

(51) Int. Cl. H05K 5/02; E05C 9/04; E05B 65/00; E05B 17/20; E05B 47/00

(52) U.S. Cl. CPC H05K 5/0221; E05B 17/20; E05B 47/0001; E05B 65/0003; E05C 9/041

(57) ABSTRACT

A locking apparatus for a switchgear cabinet comprising a plurality of doors comprises: a locking slide, which is movable between an unlocked position and a locked position; a first blocking element which is connected to the locking slide; an electrically actuable second blocking element which is configured to enter into engagement with the first blocking element in the locked position of the locking slide and which is configured to release the first blocking element on reception of an unblocking signal; for at least two doors, in each case one door-securing slide, which is movable along the respective doors between an unlocked position and a locked position and which is coupled to the locking slide in a closed position of the doors so that the locking slide and the door-securing slide are movable together; and for at least two doors, in each case at least one closure rod which is movable along the respective doors between an unlocked position and a locked position, wherein the corresponding closure rod is in engagement with a frame of the switchgear cabinet in the locked position of said closure rod. The door-securing slide engages in the corresponding closure rod in the locked position of said door-securing slide in order to prevent the closure rod from moving.

### FIELD OF THE INVENTION

The invention relates to the field of technology for the safety and security of medium-voltage and high-voltage installations. In particular, the invention relates to a locking apparatus for a switchgear cabinet. The invention also relates to a switchgear cabinet.

### BACKGROUND OF THE INVENTION

For reasons of operational safety and personal protection when dealing with switchgear cabinets that contain electrical installations, it is normally necessary to close said cabinets securely during the operation of the electrical installation.

Many switchgear cabinets exhibit a plurality of doors. In this case, all the doors should be closed and locked when the electrical installation is in operation.

DE 10 2007 051 511 B3 presents a switchgear-cabinet arrangement with a locking device which unlocks one or more secondary doors when a main door is being opened. In this case a hook element is raised by a push-rod and for the purpose of locking a door is able to fall, due to gravity, into an angular element in order to lock the respective door again.

DE 20 2012 006 108 U1 also presents a fail-safe multi-door lock for a switchgear cabinet, in the case of which several doors can be locked simultaneously. According to FIG. 1, FIG. 2 and FIG. 3 of DE 20 2012 006 108 U1, the locking apparatus 100 includes a locking slide 110 which is displaceable between an unlocked position and a locked position, a first blocking element 130 connected to the locking slide 110, and an actuatable second blocking element 120 which is designed to enter into engagement with the first blocking element 130 in the locked position of the locking slide 110. For at least two doors 520, in each instance a door-securing slide 530 is provided which is displaceable along the respective door 520 between an unlocked position and a locked position and which in a closed position of the door 520 has been coupled with the locking slide 110, so that the locking slide 110 and the door-securing slide 530 are displaceable together.

Furthermore, a safety device for a swiveling-lever rod closure for a single switchgear-cabinet door is specified in DE 20 2007 007 723 U1, wherein in FIG. 2 the single door with a closure rod 24 can be prevented by a pin 38 from being displaced. The pin 38 is actuated by a lifting magnet 26.

### SUMMARY OF THE INVENTION

The object of the invention to provide a secure and easy-to-operate switchgear cabinet.

This object is achieved by the subject-matter of the independent claims. Further embodiments of the invention result from the dependent claims and from the following description.

One aspect of the invention relates to a locking apparatus for a switchgear cabinet having a plurality of doors. The switchgear cabinet may contain a medium-voltage or high-voltage electrical installation, such as, for example, components of a frequency converter, which is enclosed by the doors and cover plates on the sides and on the ceiling of the switchgear cabinet. The doors may have been arranged alongside one another on a front side of the switchgear cabinet and, for example, may be opened about a vertical axis.

According to an embodiment of the invention, the locking apparatus includes a locking slide which is displaceable between an unlocked position and a locked position, a first blocking element connected to the locking slide, and an electrically actuatable second blocking element which is designed to enter into engagement with the first blocking element in the locked position of the locking slide and which is designed to release the first blocking element upon receiving an unblocking signal. The locking slide, which is able to hold the doors in a closed position, can in this way be prevented from moving with the blocking elements when the electrical installation inside the switchgear cabinet is energized. The locking slide may have been mounted in the frame of the switchgear cabinet and/or may exhibit an elongated, flat rod as a mechanical base element.

The locking apparatus further includes for at least two doors in each instance a door-securing slide which is displaceable along the door between an unlocked position and a locked position and which has been coupled with the locking slide in a closed position of the door, so that the locking slide and the door-securing slide are displaceable together. The door-securing slide may have been mounted in the respective door of the switchgear cabinet, so that it is displaceable in the door but can be moved jointly with the door. When the door is being closed, the door-securing slide and the locking slide engage one another so they can only be moved together. The door-securing slide may exhibit an elongated, flat rod as a mechanical base element. In other words: the door-securing slide in its locked position engages with the respective closure rod of the associated door in order to prevent a displacement of the respective closure rod, so that in this way the at least one closure rod keeps the respective door closed—that is to say, in its locked position the door-securing slide prevents the displacement of all the closure rods, so consequently all the doors are also kept closed.

The locking apparatus further includes for at least two doors in each instance at least one closure rod which is displaceable along the door between an unlocked position and a locked position, the closure rod being in engagement in its locked position with a frame of the switchgear cabinet. For example, a hook may have been fitted to the frame, which is pushed into an opening in the closure rod when the door is being closed. In the course of the displacement of the closure rod the hook then engages the edge of the opening from behind, so that the door or, to be more exact, the closure rod is held on the hook. The closure rod may exhibit, for example, a U-shaped profile with elongated holes at the base of the U.

In its locked position the door-securing slide engages with the closure rod in order to prevent a displacement of the closure rod. In this way, the closure rods are able to keep the respective door closed. The door-securing slides prevent a movement of the closure rod and are themselves prevented from moving by the locking slide. The locking slide, in turn, is prevented from moving by the two closure elements.

According to an embodiment of the invention, the closure rod is displaceable by a user between the unlocked position and the locked position by a handle being turned. For example, a toothed wheel may have been fastened to the handle, which engages with a toothed rack or with a perforated rod on the closure rod.

According to an embodiment of the invention, the locking apparatus exhibits, for each door, two closure rods which enter into engagement with the frame on opposite edges of the door. Only one of the two closure rods, for example the upper one, can in this case be prevented by the door-securing slide from being displaced. The other closure rod can be indirectly prevented from being displaced via the other closure rod via a common mechanism (such as the handle, for instance).

According to an embodiment of the invention, the closure rod is displaceable parallel to a swivel axis of the door. For example, the closure rod may have been arranged opposite the hinge of the door.

According to an embodiment of the invention, the first blocking element includes a latch which can be received in the second blocking element. The latch may have been fitted on one side of the locking slide. The second, electrically actuatable blocking element may have been fastened to the frame of the switchgear cabinet in an opposing manner.

According to an embodiment of the invention, the locking slide is displaceable in a direction at right angles to the swivel axis of the doors. In just the same way, the door-securing slide may be displaceable in a direction at right angles to the swivel axis of the doors.

According to an embodiment of the invention, at least one of the door-securing slides exhibits a handle via which a user can displace the door-securing slide. For example, the associated door may exhibit a hole in the door leaf, through which the handle protrudes. If all the doors are closed, the door-securing slide together with the locking slide can then be moved with the handle from the closed position into the open position (if this is permitted by the closure elements). In the course of this movement, the door-securing slides of the other doors are moved simultaneously into the open position. In this way, all the closure rods are released. Consequently all the doors can then be opened.

According to an embodiment of the invention, the door-securing slide includes a driving clasp which is designed to latch, in the closed position of the door, into a driving pin fastened to the locking slide. One possibility by which the door-securing slide can be fixed to the locking slide when the door is closed is a clasp fastened to the door-securing slide, which encompasses the driving pin when the door is being closed.

According to an embodiment of the invention, the locking apparatus further includes for at least two doors in each instance a blocking hook connected to the locking slide, which is designed to hold the locking slide in the unlocked position when the door is open, so that only when several doors or all the doors are closed is the locking slide capable of being pushed into the locked position. If all the doors exhibit a blocking hook of such a type, the locking slide can only be pushed into the closed or locked position when all the doors are closed.

The blocking hook may be capable of swiveling about an axis parallel to a swivel axis of the door. For example, the blocking hook may have been fitted on one side of the locking slide and may be designed to encompass a blocking pin which has been fitted to the frame of the switchgear cabinet.

According to an embodiment of the invention, the blocking hook is pressed in the direction of a blocking pin by means of a spring, in order to hold the locking slide in the open position. The blocking pin may have been fastened to the frame of the switchgear cabinet. As a result of displacement of the locking slide into the open position, the blocking hook slides over the blocking pin, and the spring prevents the blocking hook from opening again automatically.

According to an embodiment of the invention, the door-securing slide for the respective door is designed to unlock the blocking hook when the door is being closed. For example, the driving clasp, which also serves to secure the door-securing slide to the locking slide when the door is being closed, can also be used to separate the blocking hook (contrary to the action of force of the spring) from the blocking pin.

A further aspect of the invention relates to a switchgear cabinet with a locking apparatus of such a type.

According to an embodiment of the invention, the switchgear cabinet includes a frame, in which a plurality of doors have been mounted so as to be capable of swiveling, and a locking apparatus such as is described above and below. As a rule, the interior of the switchgear cabinet will have been enclosed by cover plates on the sides and on the ceiling of the switchgear cabinet, which have been fastened to the frame.

The locking slide may be displaceable relative to the frame. For example, the locking slide has been mounted on the frame.

The locking apparatus may serve to close at least two doors (and preferentially all the doors) of the switchgear cabinet when an electrical installation inside the switchgear cabinet is in operation. In this connection the electrically actuatable blocking element may have been adjusted in such a way that during the operation of the electrical installation, when the latter is energized, it holds the locking slide in place so that the doors cannot be opened.

To this end, at least two doors or even all the doors of the switchgear cabinet include, in each instance, a door-securing slide and a closure rod which are displaceable relative to the respective door and are capable of swiveling with the door. In the case of closed doors, the locking slide prevents the door-securing slides from being capable of being displaced. The door-securing slides, in turn, prevent a displacement of the closure rods which keep the doors closed.

### BRIEF DESCRIPTION OF THE FIGURES

Exemplary embodiments of the invention will be described in detail in the following with reference to the attached figures.

FIG. 1 shows a perspective view of a switchgear cabinet according to an embodiment of the invention.

FIG. 2 shows the switchgear cabinet from FIG. 1 from the front.

FIG. 3 shows a perspective view of a door-closer of the switchgear cabinet from FIG. 1.

FIG. 4 shows a perspective view of a locking apparatus according to an embodiment of the invention.

FIG. 5 shows a perspective view of the locking apparatus from FIG. 4 in the locked state.

FIG. 6 shows a perspective view of a closure rod of the switchgear cabinet from FIG. 1.

FIG. 7 shows a perspective view of a frame element of the switchgear cabinet from FIG. 1.

FIG. 8 shows a perspective view of a closure rod of the switchgear cabinet from FIGS. 1.

The reference symbols used in the figures and their meanings are listed in synoptic form in the list of reference symbols. As a matter of principle, identical or similar parts are provided with the same reference symbols.

### DETAILED DESCRIPTION OF EXEMPLARY EMBODIMENTS

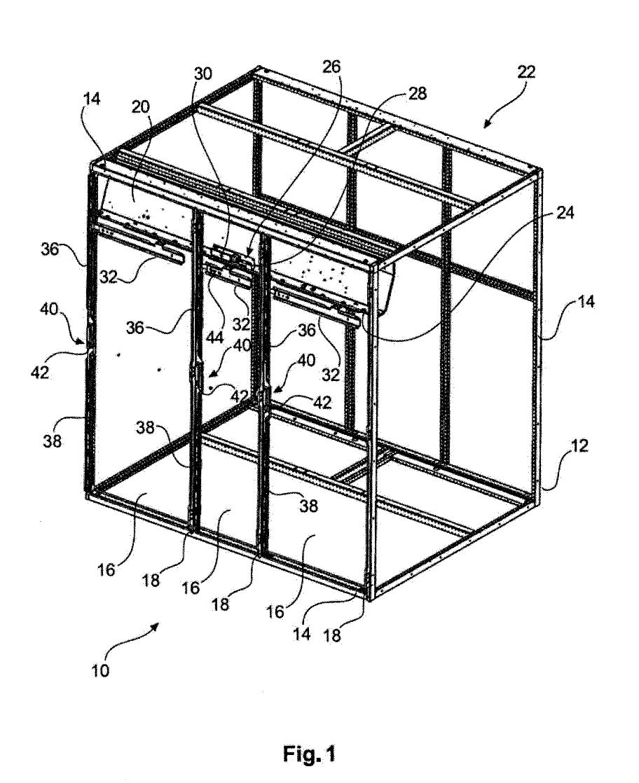

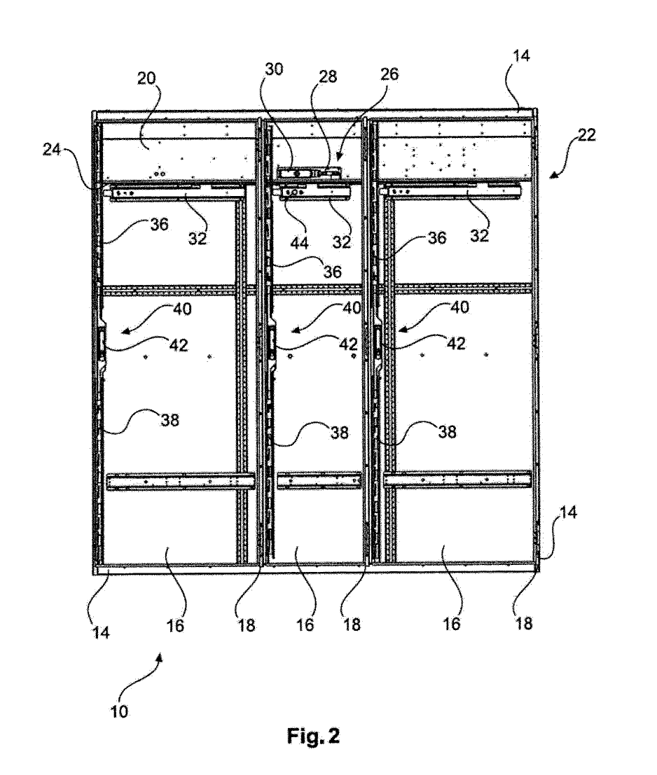

FIGS. 1 and 2 show a switchgear cabinet 10 which as a load-bearing structure includes a frame 12 which has been constructed from frame elements 14 which are arranged, inter alia, at the edges of the switchgear cabinet 10. At the sides, on the rear and/or on the top of the switchgear cabinet, cover plates (not shown in FIGS. 1 and 2) have been fastened to the frame 12, in order to seal off an electrical device inside the switchgear cabinet 10 from the environment.

Located on the front side of the switchgear cabinet 10 are doors 16 which are each capable of swiveling about a vertical axis 18. Located behind the doors on the top of the switchgear cabinet 10 is a cable duct 20 which has been fastened to the frame 12.

Cover plates that have been omitted in FIGS. 1 and 2, in order to show a locking apparatus 22 of the switchgear cabinet 10, have also been fastened to the doors 16.

The locking apparatus 22 includes a locking slide 24 in the form of a rail, which underneath the cable duct 20 is displaceable in a horizontal direction between an unlocked position and a locked position.

Fastened to the locking slide 24 is a first blocking element 26 which includes a latch 28 which can be inserted into a second blocking element 30 when the locking slide 24 is moved (as shown here, for example, to the left) into the locked position.

The second blocking element 30 may be, for example, an electrically actuatable actuator which releases the first blocking element 26 upon receiving an unblocking signal.

Each of the doors 16 includes a door-securing slide 32 which may also exhibit the form of a rail and which is displaceable along the respective door 16 in the horizontal direction between an unlocked position and a locked position. The door-securing slide 32 in this case has been fastened to the door in such a manner that it can be displaced with respect to the door and swiveled together with the door 16 about the swivel axis 18. If the doors 16 are closed, as shown in FIGS. 1 and 2, the respective door-securing slide 32 has been coupled with the locking slide 24, so that the locking slide 24 and the door-securing slide 32 are displaceable together horizontally.

Each of the doors 16 includes an upper closure rod 36 and a lower closure rod 38 which are displaceable in a vertical direction along the door 16 between an unlocked position and a locked position. In their locked position the closure rods 36, 38 are in engagement with the frame 12, so that the doors 16 cannot be opened.

Each of the doors 16 further includes a door-closer 40 which, for example, may exhibit a lock and a handle 42 with which a person, for example a maintenance mechanic, can open the respective door 16 and can unlock the door 16 by turning the handle. The handle 42 is connected to the two closure rods 36, 38 via a mechanism, so that the closure rods 36, 38 are moved up and down when the handle 42 is turned.

However, this is only possible if the closure rods 36 are not prevented from doing this by the door-securing slide 32 of the respective door 16, since the door-securing slide 32 of the door in its locked position engages with closure rod 36 (of the same door 16) in order to prevent a displacement of the closure rods 36, 38.

If the switchgear cabinet is in the locked state, the closure rods 36, 38 prevent the respective door 16 from opening, and the respective door-securing slide 32 prevents closure rod 36 from being displaced. Since the doors 16 are closed, the door securing slides 32 are coupled with the locking slide 24 and are consequently prevented by the locking slide 24 from being displaced. The locking slide 24 is prevented from being displaced via the first blocking element 26 and the second blocking element 30.

If the second blocking element 30 receives an unblocking signal (for example, if the electrical installation inside the switchgear cabinet 10 is no longer energized), the second blocking element 30 unlocks itself and releases the first blocking element 26.

A user can then push one of the door-securing slides 32 together with the locking slide 24 into the unlocked position (here, to the right). To this end, one of the door-securing slides 32 may exhibit a handle 44 which protrudes outward through an opening in a cover plate of the door 16 in question. Since the other door-securing slides 32 are also coupled with the locking slide 24, these are also pushed into the unlocked position and they release the closure rod 36.

The user can move the closure rods 36, 38 into the unlocked position and open the respective door 16 by turning the handle 42 of a door.

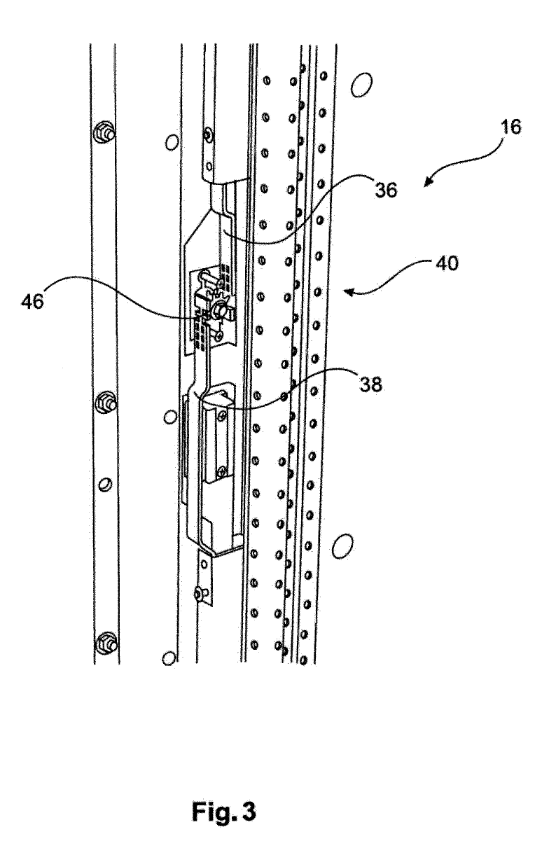

FIG. 3 shows a detail of the switchgear cabinet from FIGS. 1 and 2, which shows the door-closer 40 and a part of the closure rods 36, 38. The handle 42 is connected to a toothed wheel 46 which engages with holes in the closure rods 36, 38. If the handle 42 is turned, the toothed wheel 46 rotates and displaces the closure rods 36, 38 contrary to one another up and down. By virtue of the toothed wheel, the two closure rods 36, 38 have been coupled to one another in such a manner that the locked closure rod 36 also prevents closure rod 38 from moving.

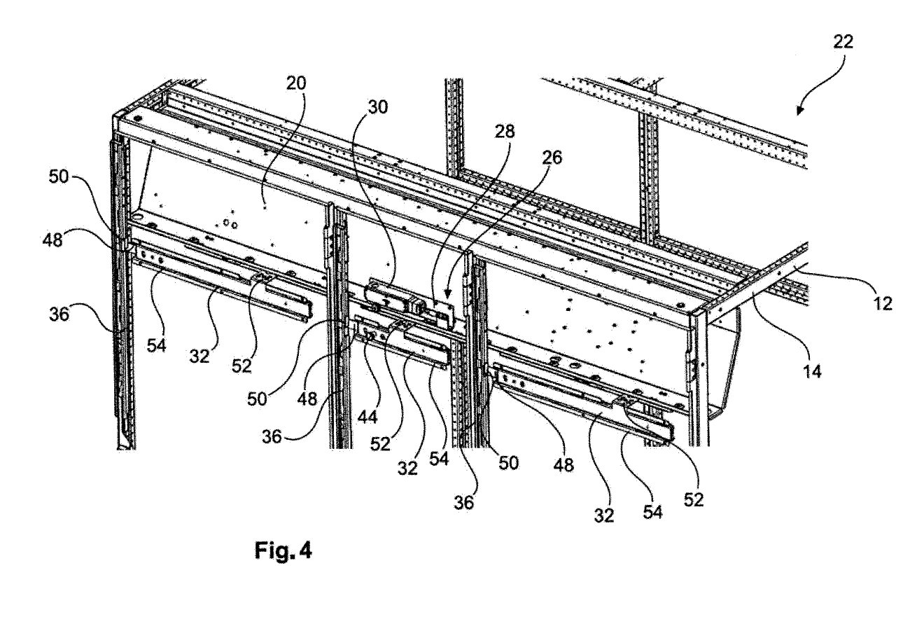

FIG. 4 shows a part of the locking apparatus 22 of the switchgear cabinet 10 in magnified form. From FIG. 4, which shows the locking slide 24 and the door-securing slides 32 in the unlocked position, it is evident that door-securing slides 32 take the form of elongated rail which exhibit at one end a latch 48 which can engage with an opening 50 in the respective closure rod 36. Furthermore, the door-securing slide 32 exhibits a driving clasp 52 which sticks out laterally from the door-securing slide 32 and can engage with the locking slide 24 when the door 16 is closed. A guide rail 54 has also been fastened to the door 16, in which the door-securing slide 32 has been mounted.

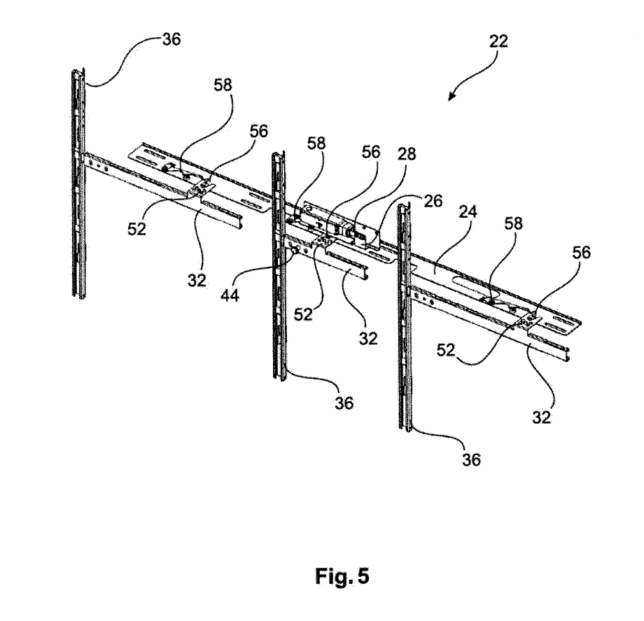

FIG. 5 shows a part of the locking apparatus 22, analogous to FIG. 4 with the locking slide 24, and the door-securing slide 32 in the locked position.

As can be discerned in FIG. 5, the driving clasp 52 of each door-securing slide 32 encompasses a respective driving pin 56 which has been fastened to the locking slide 24. In this way, the door-securing slide 32 can be coupled with the locking slide 24 when the door 16 is closed.

Furthermore, for each door-securing slide 32 in FIG. 5 a blocking hook 58 can be discerned which will be described more precisely in FIGS. 8.

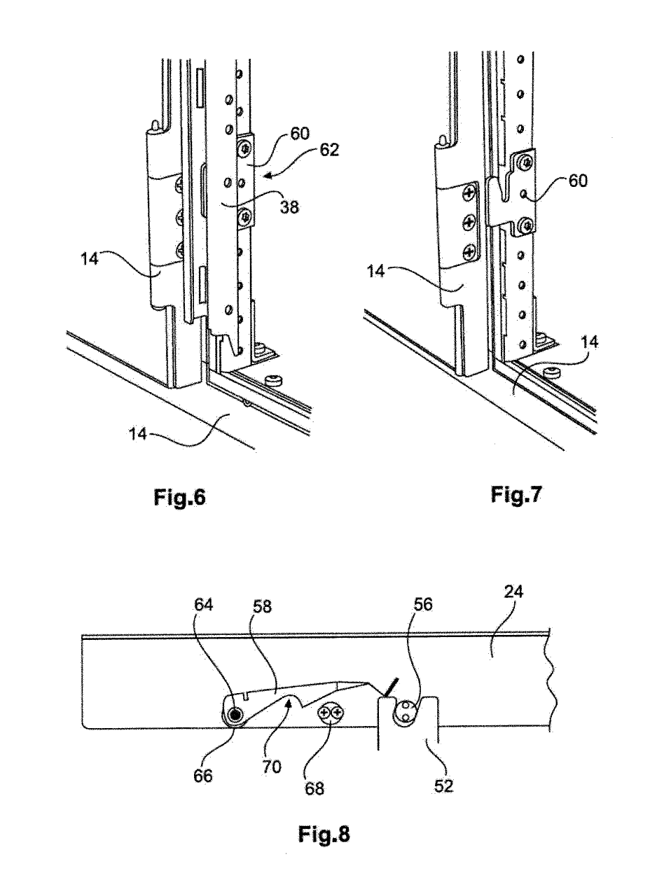

FIGS. 6 and 7 show a detail from the switchgear cabinet 10, which shows how a closure rod (here, 38) can be brought into engagement with the frame 12. An analogous (reflected) arrangement can also be formed with closure rod 36. A hook 60 has been fitted to the frame 12, which is received in a corresponding opening 62 in closure rod 38 when the door 16 is being closed. If closure rod 38 then moves downward, the hook 60 engages the edge of the opening from behind and prevents the door 16 from opening.

FIG. 8 shows a portion of the locking slide 24 with a blocking hook 58. The blocking hook 58 is capable of rotating about an axis 64 and is pressed by a spring 66 in the direction of a pin 68 which has been fastened to the frame 12 or to the cable duct 20.

If the respective door is open, the locking slide 24 is in the unlocked position, and a recess 70 of the blocking hook 58 lies on the pin 68 and prevents the locking slide 24 from being displaced.

As a result of the door 16 being closed, the driving clasp 52 not only encompasses the driving pin 56 but also pushes the blocking hook away from the pin 68. Only when all the doors 16 have been closed can the locking slide 24 again be pushed into the locked position.

In addition, it should be pointed out that “including” does not exclude any other elements or steps, and “a” or “an” does not exclude a plurality. It should furthermore be pointed out that features or steps that have been described with reference to one of the above exemplary embodiments may also be used in combination with other features or steps of other exemplary embodiments described above. Reference symbols in the claims are not to be regarded as a restriction.

### LIST OF REFERENCE SYMBOLS

10 switchgear cabinet
12 frame
14 frame element
16 door
18 axis
20 cable duct
22 locking apparatus
24 locking slide
26 first blocking element
28 latch
30 second blocking element
32 door-securing slide
36, 38 closure rod
40 door-closer
42, 44 handle
46 toothed wheel
48 latch
50 opening
52 driving clasp
54 guide rail
56 driving pin
58 blocking hook
60 hook
62 opening
64 axis
66 spring
68 pin
70 recess

1. A locking apparatus for a switchgear cabinet having a plurality of doors, the locking apparatus including:
a locking slide which is displaceable between an unlocked position and a locked position;
a first blocking element connected to the locking slide;
an electrically actuatable second blocking element which is designed to enter into engagement with the first blocking element in the locked position of the locking slide and which is designed to release the first blocking element upon receiving an unblocking signal;
for at least two doors, in each instance a door-securing slide which is displaceable along the respective door between an unlocked position and a locked position and which in a closed position of the door has been coupled with the locking slide, so that the locking slide and the door-securing slide are displaceable together;
for at least two doors, in each instance at least one closure rod which is displaceable along the respective door between an unlocked position and a locked position, wherein the respective closure rod in its locked position is in engagement with a frame of the switchgear cabinet;
wherein the door-securing slide in its locked position engages with the respective closure rod in order to prevent a displacement of the respective closure rod.

2. The locking apparatus as claimed in claim 1,
wherein the closure rod is displaceable by a user between the unlocked position and the locked position by a handle being turned.

3. The locking apparatus as claimed in claim 1,
wherein the locking apparatus exhibits, for each door, two closure rods which enter into engagement with the frame on opposite edges of the door.

4. The locking apparatus as claimed in claim 1,
wherein the closure rod is displaceable parallel to a swivel axis of the door.

5. The locking apparatus as claimed in claim 1,
wherein the first blocking element includes a latch which is capable of being received in the second blocking element.

6. The locking apparatus as claimed in claim 1,
wherein the locking slide is displaceable in a direction at right angles to the swivel axis of the doors.

7. The locking apparatus as claimed in claim 1,
wherein the door-securing slide is displaceable in a direction at right angles to the swivel axis of the doors.

8. The locking apparatus as claimed in claim 1,
wherein at least one of the door-securing slides exhibits a handle via which a user can displace the door-securing slide.

9. The locking apparatus as claimed in claim 1,
wherein the door-securing slide includes a driving clasp which is designed to latch, in the closed position of the door, into a driving pin fastened to the locking slide.

10. The locking apparatus as claimed in claim 1, further including:
for at least two doors, in each instance a blocking hook connected to the locking slide, which is designed to hold the locking slide in the unlocked position when the door is open, so that only when a plurality of doors are closed can the locking slide be pushed into the locked position.

11. The locking apparatus as claimed in claim 10,
wherein the blocking hook is capable of swiveling about an axis parallel to a swivel axis of the door.

12. The locking apparatus as claimed in claim 10,
wherein the blocking hook is pushed by means of a spring in the direction of a blocking pin in order to hold the locking slide in the open position.

13. The locking apparatus as claimed in claim 10,
wherein the door-securing slide for the respective door is designed to unlock the blocking hook when the door is being closed.

14. A switchgear cabinet including:
a frame in which a plurality of doors have been mounted so as to be capable of swiveling;
a locking apparatus as claimed in comprising:
a locking slide which is displaceable between an unlocked position and a locked position;
a first blocking element connected to the locking slide;
an electrically actuatable second blocking element which is designed to enter into engagement with the first blocking element in the locked position of the locking slide and which is designed to release the first blocking element upon receiving an unblocking signal;
for at least two doors, in each instance a door-securing slide which is displaceable along the respective door between an unlocked position and a locked position and which in a closed position of the door has been coupled with the locking slide, so that the locking slide and the door-securing slide-are displaceable together;
for at least two doors, in each instance at least one closure rod which is displaceable along the respective door between an unlocked position and a locked position, wherein the respective closure rod in its locked position is in engagement with a frame of the switchgear cabinet;
wherein the door-securing slide in its locked position engages with the respective closure rod in order to prevent a displacement of the respective closure rod;
wherein the locking slide is displaceable relative to the frame;
wherein at least two doors include, in each instance, a door-securing slide and a closure rod which are displaceable relative to the respective door and are capable of swiveling with the door.

15. The locking apparatus as claimed in claim 1, wherein the closure rod is displaceable by a user between the unlocked position and the locked position by a handle being turned;
wherein the locking apparatus exhibits, for each door, two closure rods which enter into engagement with the frame on opposite edges of the door;
wherein the closure rod is displaceable parallel to a swivel axis of the door.

16. The locking apparatus claimed in claim 15, wherein the first blocking element includes a latch which is capable of being received in the second blocking element.

17. The locking apparatus as claimed in claim 15, wherein the locking slide is displaceable in a direction at right angles to the swivel axis of the doors;
wherein the door-securing slide is displaceable in a direction at right angles to the swivel axis of the doors.

18. The locking apparatus as claimed in claim 1, wherein the door-securing slide includes a driving clasp which is designed to latch, in the closed position of the door, into a driving pin fastened to the locking slide;
which further includes for at least two doors, in each instance a blocking hook connected to the locking slide, which is designed to hold the locking slide in the unlocked position when the door is open, so that only when a plurality of doors are closed can the locking slide be pushed into the locked position.
